(19) United States
(12) Patent Application Publication
(10) Pub. No.: US 2006/0233292 A1
(43) Pub. Date: Oct. 19, 2006

(54) Synchronizing signal generating device and method for serial communication

(75) Inventor: Hisanori Miura, Gamagori-city (JP)

Correspondence Address: HARNESS, DICKEY & PIERCE, P.L.C., P.O. BOX 828, BLOOMFIELD HILLS, MI, 48303, US

(73) Assignee: DENSO Corporation, Kariya-city (JP)

(21) Appl. No.: 11/402,592

(22) Filed: Apr. 12, 2006

(30) Foreign Application Priority Data
Apr. 15, 2005 (JP) 2005-118438

(51) Int. Cl. H04L 7/04; H03D 3/24

(52) U.S. Cl. 375/362; 375/376

(57) ABSTRACT

A synchronizing signal generating device for serial communication is constructed with a reference clock circuit, a phase comparator, a PLL filter, VCO and a frequency dividing circuit. The PLL filter continually outputs an unchanged voltage signal when the phase differential signal is within a predetermined range determined by the upper and lower limit values of the phase difference. As a result, noise occurring in connection with variation of the frequency of a synchronizing signal every predetermined period is suppressed.

### CROSS REFERENCE TO RELATED APPLICATION

This application is based on and incorporates herein by reference Japanese Patent Application No. 2005-118438 filed on Apr. 15, 2005.

### FIELD OF THE INVENTION

The present invention relates to a synchronizing signal generating device and method for generating a synchronizing signal for serial communication.

### BACKGROUND OF THE INVENTION

A passenger protecting device for protecting passengers when a vehicle crashes is mounted in many vehicles. For example, a passenger protecting device is disclosed in JP-A-2004-256026. This passenger protecting device is constructed with plural sensors, an electronic control unit (ECU), and plural airbag driving devices. An impact detected by the sensors is transmitted to the ECU through communications. The ECU determines the presence or absence of a vehicle crash and also identifies the crash place on the basis of the thus-detected impact. Furthermore, on the basis of the determination result, the ECU expands the airbags corresponding to the crash place through the airbag driving device to protect the passengers.

Serial communication is used for the communications between each sensor and the ECU. Data relating to the crash detected by the sensor are transmitted as variation of a voltage or current bit by bit in synchronism with a synchronizing clock. Therefore, noise containing the frequency component of the synchronizing clock and higher harmonic wave components thereof occurs from a communication line that connects the ECU and each sensor in connection with the variation of the voltage or current. The communication line is disposed in the vicinity of a radio antenna attached to the rear window, and thus the noise thus occurring affects the radio. The frequency of the synchronizing clock is determined by the number of the sensors, the data amount thereof, etc. For example when the frequency of the synchronizing clock is equal to 100 kHz, the higher harmonic wave components of the occurring noise affect the AM radio band (500 kHz to 1600 kHz), and thus induce noise in the radio.

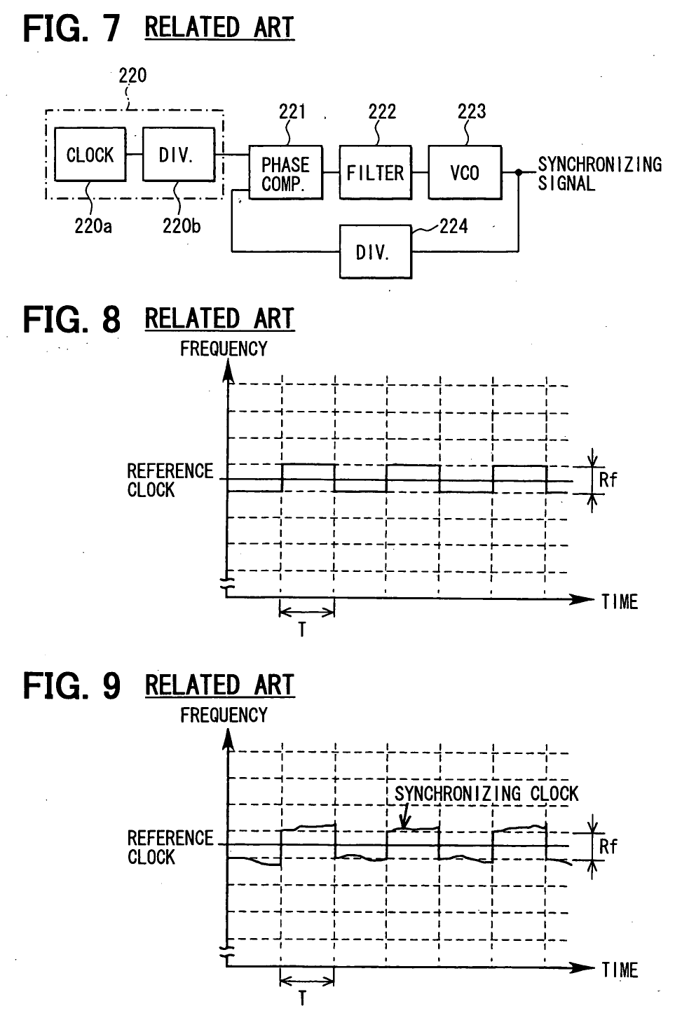

This problem may be solved by reducing the frequency of the synchronizing clock to suppress the effect of the higher harmonic wave components of the noise on the AM band of the radio. Therefore, it is proposed to vary the frequency of the synchronizing clock in accordance with the number of sensors and the data amount thereof. For instance, such a synchronizing clock generating circuit may be constructed as shown in FIG. 7 to control the frequency by phase-locked loop (PLL).

The synchronizing clock generating circuit is constructed with a reference clock circuit 220, a phase comparator 221, a PLL filter 222, a voltage-controlled oscillator (VCO) 223 and a frequency-dividing circuit 224. The reference clock circuit 220 comprises a clock circuit 220a and a frequency-dividing circuit 220b. The reference clock circuit 220 generates a reference clock having a predetermined frequency. The phase comparator 221 compares the phase of the reference clock with the phase of the synchronizing clock fed back through the frequency-dividing circuit 224 every predetermined loop period T, and outputs the phase differential signal corresponding to the phase difference. The PLL filter 222 converts the phase differential signal to a voltage signal and then outputs the voltage signal. The VCO 223 adjusts the frequency of the synchronizing clock in accordance with the voltage signal. Thus, the synchronizing clock having no phase difference, the frequency of which is coincident with the frequency of the reference clock, can be stably output. Furthermore, the frequency of the synchronizing clock can be varied by changing the frequency division ratio of the frequency dividing circuit.

However, a voltage signal output from the PLL filter 222 takes only a discrete value determined by its resolution Rf, and thus the frequency of the synchronizing clock is not perfectly coincident with the frequency of the reference clock. In the frequency of the synchronizing clock, a higher frequency than the frequency of the reference clock and a lower frequency than the frequency of the reference clock are alternately repetitively varied every predetermined loop period as shown in FIG. 8. The varying frequency width is determined by the resolution Rf of the PLL filter 222.

Furthermore, the frequency of the synchronizing clock is gradually displaced during the loop period due to the dispersion in characteristic of the circuit component parts and temperature drift as shown in FIG. 9. When the frequency of the synchronizing clock varies in the width of 0.5 kHz with 100 kHz set at the center, for example, the noise of 900 kHz which corresponds to a ninth order harmonic wave component varies in the width of 4.5 kHz every loop period. Therefore, the tone color of noise in the AM radio band varies every loop period. Even when it is a small noise, it jars very unpleasantly on the ear. In order to avoid this problem, there may be considered a method of shortening the loop period or enhancing the resolution Rf of the PLL filter to reduce the width of the varying frequency. However, this method is complicated in circuit construction, resulting in increase of the cost.

### SUMMARY OF THE INVENTION

The present invention has an object to provide a synchronizing signal generating device and method for serial communication that can suppress cost-up and suppress noise occurring in connection with variation of the frequency of a synchronizing signal every predetermined period.

According to one aspect of the present invention, a synchronizing signal is generated from a reference signal having a predetermined frequency. A phase of the reference signal with a phase of a feedback signal corresponding to the synchronizing signal is compared and a phase differential signal corresponding to a phase difference between the phases is output. The frequency of the synchronizing signal to be output every predetermined period is adjusted on the basis of the phase differential signal only when the phase differential signal is outside a range defined by an upper limit value and a lower limit value.

### DETAILED DESCRIPTION OF THE DRAWINGS

The above and other objects, features and advantages of the present invention will become more apparent from the following detailed description made with reference to the accompanying drawings. In the drawings:

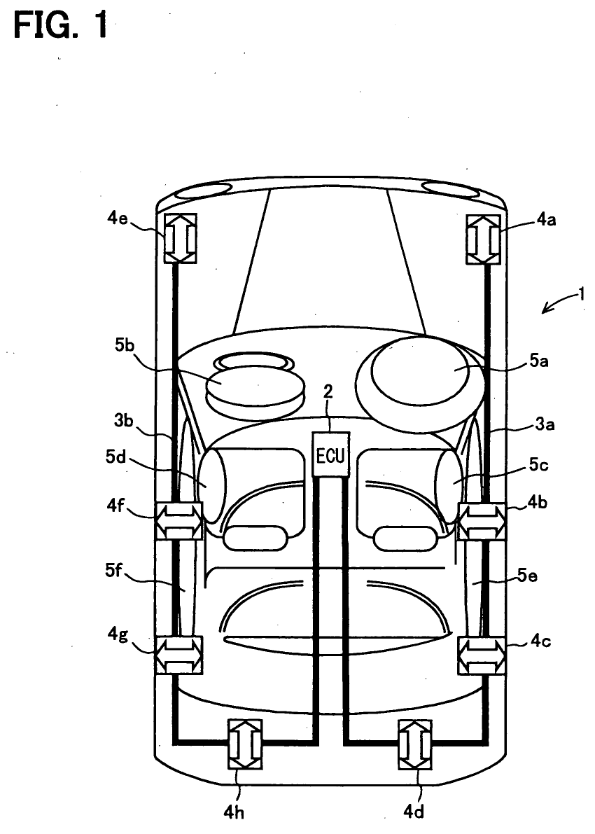

FIG. 1 is a top plan view showing an airbag system using a synchronizing signal generating device according to an embodiment of the invention;

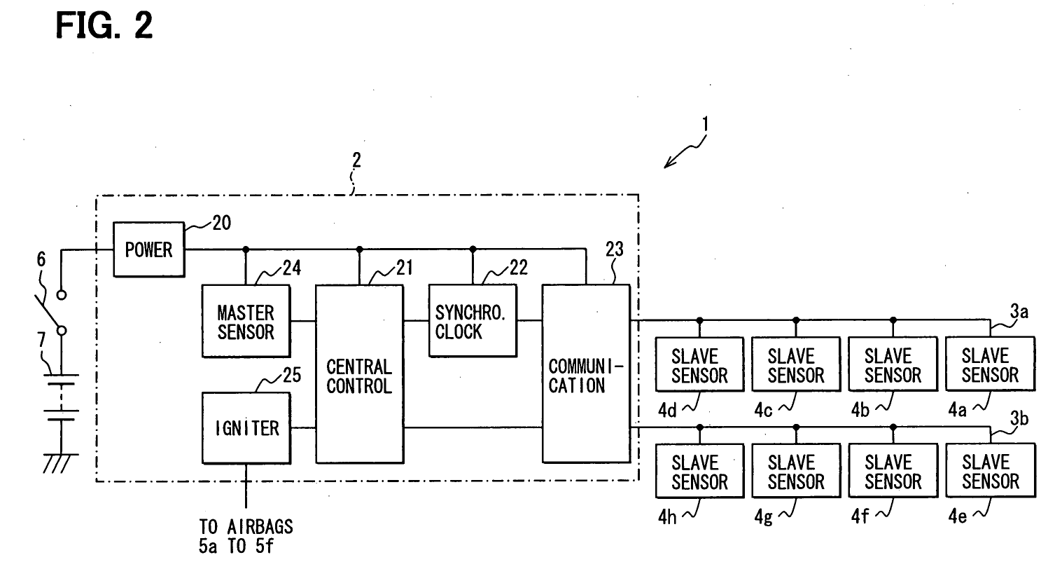

FIG. 2 is a block diagram showing the airbag system shown in FIG. 1;

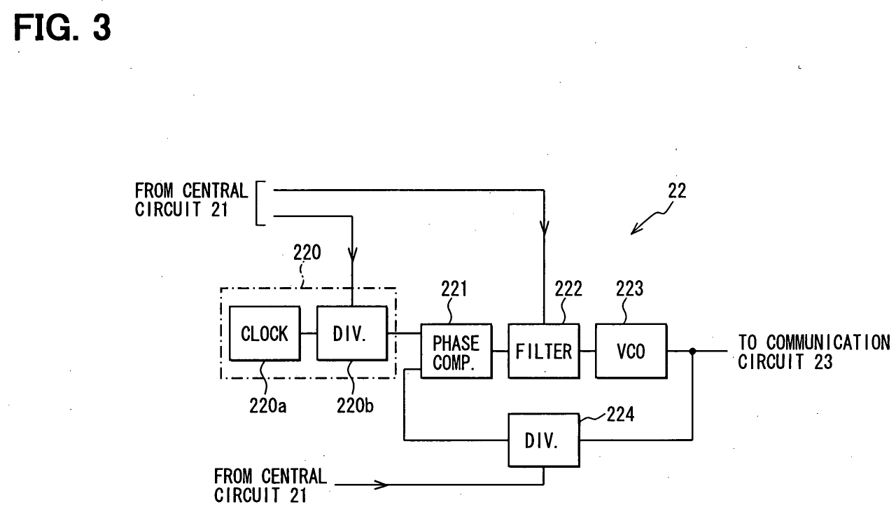

FIG. 3 is a block diagram showing a synchronizing clock circuit used in the embodiment;

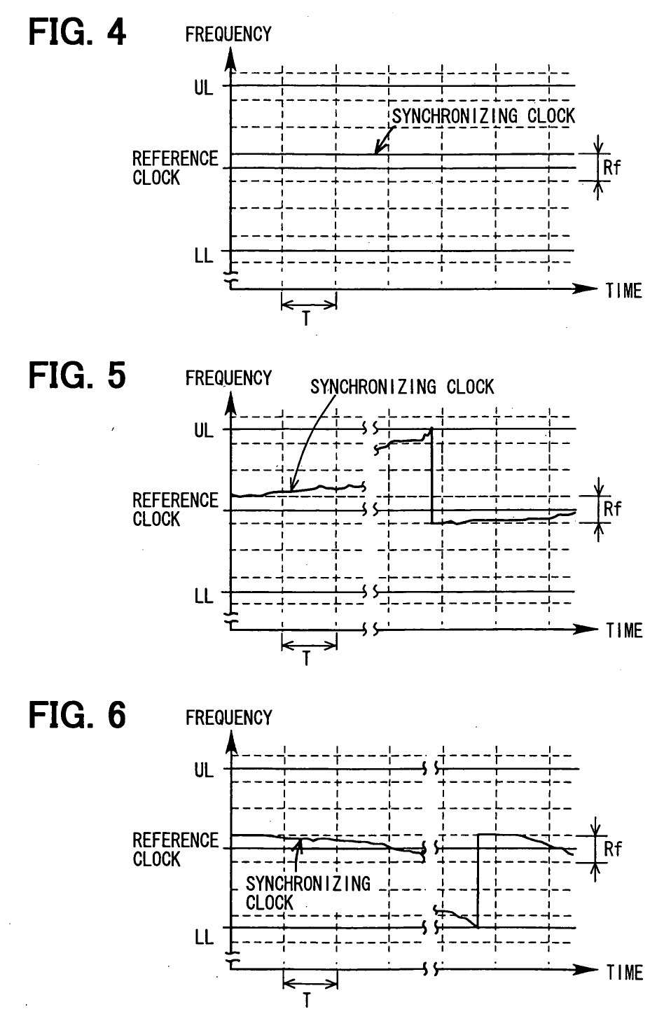

FIG. 4 is a graph showing a time variation of frequency of a synchronizing clock;

FIG. 5 is a graph showing a time variation when the frequency of the synchronizing clock is increased;

FIG. 6 is a graph showing a time variation when the frequency of the synchronizing clock is reduced;

FIG. 7 is a block diagram showing a synchronizing clock generating circuit according to a related art;

FIG. 8 is a graph showing a time variation of frequency of the synchronizing clock in the related art; and

FIG. 9 is a graph showing a frequency variation of the synchronizing clock in the related art.

### DETAILED DESCRIPTION OF THE PREFERRED EMBODIMENTS

In the following embodiment, a synchronizing signal generating device for serial communication is applied to an airbag system for protecting passengers of a vehicle.

As shown in FIG. 1, an airbag system 1 includes an airbag ECU 2, communication lines 3a, 3b, slave sensors 4a to 4h, a front airbag 5a for a driver's seat, a front airbag 5b for an assistant driver's seat, body side airbags 5c, 5d and head side (curtain) airbags 5e, 5f.

The airbag ECU 2 is a device for expanding the front airbag 5a for the driver's seat, the front airbag 5b for the assistant driver's seat, the body side airbags 5c, 5d and the head side airbags 5e, 5f on the basis of the acceleration detected by a master sensor 24 disposed in the airbag ECU 2 and the slave sensors 4a to 4h. The airbag ECU 2 is disposed substantially at the center portion of the vehicle.

The communication lines 3a, 3b are for transmission/reception of data between the airbag ECU 2 and the slave sensors 4a to 4h. The slave sensors 4a to 4d are connected to the communication line 3a, and the slave sensors 4e to 4h are connected to the communication line 3b. The communication lines 3a, 3b to which the slave sensors 4a to 4h are connected are connected to the airbag ECU 2.

The slave sensors 4a to 4h are for detecting the accelerations at the respective parts of the vehicle and transmitting the detection results through the communication lines 3a, 3b in response to a data transmission request from the airbag ECU 2. The slave sensors 4a, 4d, 4e, 4h are for detecting the acceleration in the front-and-rear direction of the vehicle. The slave sensors 4a, 4e are disposed at the right and left parts of the front portion of the vehicle, and the slave sensors 4d, 4h are disposed at the right and left parts of the rear portion of the vehicle. The slave sensors 4b, 4c, 4f, 4g detects the acceleration in the right and left direction of the vehicle. The slave sensors 4b, 4f are disposed in the neighborhood of the B pillars at the right and left parts of the vehicle side portions. The slave sensors 4c, 4g are disposed in the neighborhood of the C pillars at the right and left parts of the vehicle side portions.

As shown in FIG. 2, the airbag ECU 2 includes a power supply circuit 20, a central control circuit 21, a synchronizing clock circuit 22 for generating a synchronizing signal for serial communication, a communication circuit 23, a master sensor 24 and an igniter circuit 25.

The power supply circuit 20 is for converting the output voltage of a storage battery 7 supplied through an ignition switch 6 to a voltage suitable for the operation of the central control circuit 21, the synchronizing clock circuit 22, the communication circuit 23 and the master sensor 24. The input terminal of the power supply circuit 20 is connected to the anode of the battery 7 through the ignition switch 6, and the cathode of the battery 7 is grounded to the vehicle. The output terminal of the power supply circuit 20 is connected to the power supply terminal of each of the central control circuit 21, the synchronizing clock circuit 22, the communication circuit 23 and the master sensor 24.

The central control circuit 21 collects acceleration data of the slave sensors 4a to 4h through the communication circuit 23, determines on the basis of the acceleration data thus collected and the acceleration data of the master sensor 24 whether each airbag is expanded or not, and controls the igniter circuit 25 on the basis of the determination result. The central control circuit 21 outputs the upper and lower limit values UL and LL of the phase difference and the frequency division ratio to the synchronizing clock circuit 22. The upper and lower limit values of the phase difference and the frequency division ratio are set values for regulating the PLL operation of the synchronizing clock circuit 22. Furthermore, the central control circuit 21 outputs a data transmission request instruction to the slave sensors 4a to 4h to the communication circuit 23. The data transmission request instruction indicates one slave sensor and requests the thus-indicated slave sensor to transmit data. Furthermore, on the basis of the acceleration data of the slave sensors 4a to 4h output from the communication circuit 23 and the acceleration data output from the sensor 25, it is determined whether each airbag is to be expanded or not, and an ignition signal is output to the igniter circuit 25 on the basis of the determination result. The ignition signal is output to only an airbag which is required to be expanded. The central control circuit 21 is connected to the synchronizing clock circuit 22, the communication circuit 23, the sensor 24 and the igniter circuit 25.

The synchronizing clock circuit 22 outputs a synchronizing clock for serial communication between the airbag ECU 2 and the slave sensors 4a to 4h. As shown in FIG. 3, the synchronizing clock circuit 22 includes a reference clock circuit 220 for generating a reference signal, a phase comparator 221, a PLL filter 222, VCO 223 for generating a synchronizing signal and a frequency dividing circuit 224 as a feedback circuit.

The reference clock circuit 220 outputs a reference clock having a predetermined fixed frequency. The reference clock circuit 220 includes a clock circuit 220 and a frequency dividing circuit 220b. The phase comparator 221, the PLL filter 222 and VCO 223 are connected to one another in series. One input terminal of the phase comparator 221 is connected to the reference clock circuit 220. The other input terminal is connected to the output terminal of VCO 223 through the frequency dividing circuit 224. Furthermore, the output terminal of VCO 223 is connected to the communication circuit 23, and the frequency dividing circuits 220b, 224 and the control terminal of the PLL filters 222 are connected to the central control circuit 21 respectively.

The clock circuit 220a continually outputs a reference clock having a fixed frequency. The frequency dividing circuit 220b divides the frequency of the clock on the basis of the frequency division ratio set by the central control circuit 21. The clock circuit 220a and the frequency dividing circuit 220b are connected to each other in series. The phase comparator 221 compares the phase of a synchronizing clock fed back through the frequency dividing circuit 224 with the phase of the reference clock, and outputs a phase differential signal corresponding to the phase difference.

The PLL filter 222 converts the phase differential signal to a voltage signal every predetermined period T, and outputs the voltage signal thus converted. When the phase differential signal is between a phase difference upper limit value UL and a phase differential lower limit value LL set by the central control circuit 21, that is, not more than the phase differential upper limit value UL and also not less than the phase differential lower limit value LL, the PLL filter 222 continually outputs the voltage signal without changing it or limiting it. VCO 223 outputs the clock having the frequency corresponding to the voltage signal as the synchronizing clock. The frequency dividing circuit 224 divides the frequency of the synchronizing clock on the basis of the frequency division ratio set by the central control circuit 21, and feeds it back to the phase comparator 221.

Returning to FIG. 2, the communication circuit 23 transmits/receives the data transmission request instruction and the acceleration data to/from the slave sensors 4a to 4h through the communication lines 3a, 3b. The communication circuit 23 serially communicates the data transmission request instruction from the central control circuit 21 to the slave sensors 4a to 4h one by one in synchronism with the synchronizing clock. The data transmission request instruction is represented by voltage variation, for example. “1” or “0” is determined on the basis of the ratio of “high level” and “low level” in each period of the synchronizing clock.

Furthermore, the communication circuit 23 outputs to the central control circuit 21 the acceleration data from the slave sensors 4a to 4h which are serially-communicated in synchronism with the next data transmission request instruction. The acceleration data is represented by current variation, for example. “1” or “0” is determined on the basis of whether the current level after a half period elapses from the start time of each period of the synchronizing clock is higher or lower than a predetermined value. The communication circuit 23 is connected to the slave sensors 4a to 4d through the communication line 3a, and connected to the slave sensors 4e to 4h through the communication line 3b. Furthermore, the communication circuit 23 is connected to the central control circuit 21 and the synchronizing clock circuit 22.

The master sensor 24 is mounted in the airbag ECU 2 to detect the acceleration in the front-and-rear direction of the vehicle. The master sensor 24 is connected to the central control circuit 21 and outputs the detection result to the central control circuit 21. The igniter circuit 25 is connected to the central control circuit 21 and each of the airbags 5a to 5f to activate each airbag on the basis of the ignition signal output from the central control circuit 21.

Each of the slave sensors 4a to 4h determines on the basis of the data transmission request instruction serially-communicated from the communication circuit 23 whether the slave sensor concerned is a communication target. Furthermore, when the slave sensor concerned is a communication target, the slave sensor concerned converts the detection result of the acceleration to acceleration data, and serially communicates the acceleration data to the communication circuit 23 in synchronism with the next data transmission request instruction.

Next, the specific operation will be described with further reference to FIGS. 4 to 6. When the ignition switch 6 is turned on, the power supply circuit 20 converts the output voltage of the battery 7 to the voltage suitable for the operation of the central control circuit 21, the synchronizing clock circuit 22, the communication circuit 23 and the master sensor 24, and outputs the thus-converted voltage to these circuits. The central control circuit 21, the synchronizing clock circuit 22, the communication circuit 23 and the master sensor 24 thus start to operate.

The central control circuit 21 sets phase differential upper and lower limit values UL and LL in the PLL filter 222, and also sets the frequency division ratio in the frequency dividing circuits 220b, 224. The reference clock circuit 220 divides the frequency of a clock having the fixed frequency on the basis of the set frequency division ratio, and outputs it as the reference clock. The phase comparator 221 compares the phase of the frequency-divided synchronizing clock fed back through the frequency dividing circuit 224 with the phase of the reference clock, and outputs the phase differential signal corresponding to the phase difference. The phase differential signal is converted to the voltage signal every predetermined period T in the PLL filter 222. However, when the phase differential signal is not more than the phase differential upper limit value UL and also not less than the phase differential lower value LL, the previous voltage signal is continually output. Therefore, VCO 223 continually outputs the synchronizing clock having such a frequency that the phase difference between the frequency-divided synchronizing clock and the reference clock is within a predetermined range determined by the phase differential upper and lower limit values UL and LL as shown in FIG. 4. In this figure, the limit values UL and LL are shown as being converted to corresponding frequencies. The frequency of the synchronizing clock is a discrete value determined by the resolution Rf of the PLL filter 222.

The frequency of the synchronizing clock gradually deviates due to dispersion in characteristic of circuit component parts or temperature drift. However, as shown in FIG. 5, even when the frequency of the synchronizing clock gradually increases with the time lapse, the frequency adjustment every predetermined period T is not carried out until the phase difference exceeds the phase differential upper limit value LL. Furthermore, as shown in FIG. 6, even when the frequency of the period clock is gradually reduced with the time lapse, the frequency adjustment of every predetermined period T is not carried out until the phase difference exceeds the phase differential lower limit value LL. Even when the frequency of the synchronizing clock is varied as described above, no problem would occur if the phase differential upper and lower limit values UL and LL are set to values in such a range that the serial communication is not adversely affected. Accordingly, the synchronizing clock circuit 22 outputs the synchronizing clock for which the frequency adjustment every predetermined period T is suppressed.

The central control circuit 21 outputs to the communication circuit 23 the data transmission request instruction to the slave sensors 4a and 4e. The communication circuit 23 serially communicates to the communication line 3a the data transmission request instruction to the slave sensor 4a in synchronism with the synchronizing clock. Furthermore, it serially communicates to the communication line 3b the data transmission request instruction to the slave sensor 4e in synchronism with the synchronizing clock. At the same timing, the data transmission request instructions to the slave sensors 4b to 4d, 4f to 4h are serially communicated from the communication circuit 23 to the communication lines 3a, 3b.

On the basis of the data transmission request instruction serially-communicated from the communication circuit 23, each of the slave sensors 4a to 4h determines whether the slave sensor concerned is a communication target. If the slave sensor concerned is a communication target, it converts the detection result of the acceleration to the acceleration data, and serially communicates the acceleration data to the communication circuit 23 in response to the next data transmission request instruction. The communication circuit 23 outputs the acceleration data from the serially-communicated slave sensors 4a to 4h to the central control circuit 21.

On the basis of the thus-collected acceleration data from the slave sensors 4a to 4h and the acceleration data of the master sensor 24, the central control circuit 21 determines whether each airbag should be activated or not. Furthermore, on the basis of the determination result, it outputs the ignition signal to the igniter circuit 25. The igniter circuit 25 expands the airbags on the basis of the ignition signal output from the central control circuit 21, and protects the passengers of the vehicle.

According to this embodiment, by the simple construction of continually outputting the voltage signal unchanged when the phase differential signal is within the predetermined range determined by the phase differential upper and lower limit values UL and LL, cost-up can be suppressed, and noise occurring in connection with the frequency variation of the synchronizing clock every predetermined period T can be suppressed. Furthermore, the frequency of the synchronizing clock can be surely adjusted on the basis of the phase differential signal by the PLL filter 222 and VCO 223. Still furthermore, the phase differential upper and lower limit values and the frequency division ratio are set by the central control circuit 21, whereby the synchronizing clock can be properly controlled.

The above embodiment may be modified in many other ways without departing from the spirit of the invention.

What is claimed is:

1. A synchronizing signal generating device for serial communication comprising:
a reference signal generating means for generating a reference signal having a predetermined frequency;
a phase comparing means for comparing a phase of the reference signal with a phase of a feedback signal and outputting a phase differential signal corresponding to a phase difference between the phases;
a frequency adjusting means for adjusting a frequency of a serial communication synchronizing signal to be output every predetermined period on the basis of the phase differential signal; and
a feedback means for feeding back the serial communication synchronizing signal as the feedback signal to the phase comparing means,
wherein the frequency adjusting means ceases to adjust the frequency of the serial communication synchronizing signal when the phase differential signal is between an upper limit value and a lower limit value of the phase difference.

2. The synchronizing signal generating device for serial communication according to claim 1, wherein the frequency adjusting means includes:
a control circuit for outputting a control signal corresponding to the phase differential signal every predetermined period; and
a synchronizing signal generator for outputting the serial communication synchronizing signal having the frequency corresponding to the control signal,
wherein the control circuit continually outputs the output control signal unchanged when the phase differential signal is between the upper limit value of and the lower limit value of the phase difference.

3. The synchronizing signal generating device for serial communication according to claim 1, wherein at least one of the upper limit value and the lower limit value of the phase difference is set by an external device to be connected.

4. A synchronizing signal generating method for serial communication comprising steps of:
generating a reference signal having a predetermined frequency;
comparing a phase of the reference signal with a phase of a feedback signal and outputting a phase differential signal corresponding to a phase difference between the phases;
setting upper limit value and lower limit value of a phase difference of the reference signal and the feedback signal;
adjusting a frequency of a serial communication synchronizing signal to be output every predetermined period on the basis of the phase differential signal only when the phase differential signal is outside a range defined by the upper limit value and the lower limit value; and
feeding back the serial communication synchronizing signal as the feedback signal to the phase comparing means.

5. The synchronizing signal generating method for serial communication according to claim 4 further comprising steps of:
transmitting output data of a sensor device mounted in a vehicle in synchronism with the serial communication synchronizing signal to an electronic control circuit; and
processing the output data to activate an actuator device mounted in the vehicle.
